(19) United States
(12) Patent Application Publication
(10) Pub. No.: US 2016/0308067 A1
(43) Pub. Date: Oct. 20, 2016

(54) Metal oxynitride transistor devices

(71) Applicants: Ishiang Shih, Brossard (CA); Cindy X. Qiu, Brossard (CA); Andy Shih, Brossard (CA); Yi-Chi Shih, Los Angeles, CA (US); Chunong Qiu, Brossard (CA); Julia Qiu, Brossard (CA)

(72) Inventors: Ishiang Shih, Brossard (CA); Cindy X. Qiu, Brossard (CA); Andy Shih, Brossard (CA); Yi-Chi Shih, Los Angeles, CA (US); Chunong Qiu, Brossard (CA); Julia Qiu, Brossard (CA)

(21) Appl. No.: 14/545,285

(22) Filed: Apr. 17, 2015

(51) Int. Cl. H01L 29/786; H01L 29/423; H01L 29/417

(52) U.S. Cl. CPC H01L 29/78696; H01L 29/7869; H01L 29/41733; H01L 29/42384

(57) ABSTRACT

A thin film transistor with a first metal oxynitride channel layer or a first metal oxide channel layer is provided to have controlled channel doping concentrations in a bottom surface region, a central channel region and a top surface region so that doping concentration ratios between the bottom surface region and the central channel region and between the top surface region and the central channel region are greater than a first threshold doping ratio and less than a second threshold doping ratio in order to retain more uniform charge carrier mobility values in the first channel layer and to improve the performance of the thin film transistor devices.

### FIELD OF INVENTION

This invention relates to transistors having a metal oxynitride channel layer or a metal oxide channel layer for forming a circuit for power switching or for microwave amplification.

### BACKGROUND OF THE INVENTION

In semiconductor devices, the electronic and optoelectronic performance is determined by several parameters such as band gap, charge carrier density, charge carrier mobility and lifetime of the charge carriers. For unipolar devices like field effect transistor (FET) or thin film transistor (TFT), electron carrier mobility at room temperature is a key parameter which affect the transconductance and the ON state channel resistance of the devices. Device performance improves as the charge carrier mobility is increased. In monocrystalline semiconductors Si and GaAs, the mobility is mainly limited by scattering with acoustic phonons and scattering with ionized impurity. For operations in a room environment near room temperature, the charge carrier mobility in a semiconductor decreases with the increase in ionized impurity density.

Other than Si and GaAs devices, there are electronic devices with an active channel layer made of compound semiconductor such as GaN, InN, InGaN, In₂O₃, InN and InON etc. In these devices, thin films of metal nitride, metal oxide and metal oxynitride are deposited to form an active channel layer for high mobility transistor (HEMT) or thin film transistor (TFT). The performance of these thin film transistors is mainly determined by mobility of the charge carriers. These metal nitride, metal oxide and metal oxynitride thin films are normally deposited by methods including molecular beam epitaxy (MBE), metal organic chemical vapour deposition (MOCVD), reactive sputtering or reactive evaporation. All these deposition methods are performed in a reduced atmosphere or in a vacuum environment.

Due to loss of oxygen or nitrogen atoms to the adjacent layers (e.g. gate oxide layer) or into the atmosphere during the deposition, charge carrier concentration across the thickness of the active channel layer is often non-uniform in these devices. More specifically, the donor concentration in the bottom surface region and the top surface region of the channel layer is significantly larger than the carrier concentration or donor concentration in the central bulk region. Consequently, the larger donor concentration in the bottom and the top surface regions causes the charge carrier mobility in these surface regions to be low due to scatterings. Therefore, overall average mobility in the active channel layer is substantially smaller than the mobility value in the central bulk region. To overcome this problem, it is thus advantageous to develop an improved thin film transistors with controlled doping concentration profile across the thickness of the channel layer so that an improved average charge carrier mobility can be obtained in the channel layer to better the performance of the transistors.

### OBJECTS OF THE INVENTION

One objective of the invention is to provide a metal oxynitride thin film transistor device having a first metal oxynitride channel layer with a controlled doping concentration profile in the first channel layer so that doping concentration ratios between a bottom surface region and a central channel region and between a top surface region and the central channel region are greater than a first threshold doping concentration ratio value and smaller than a second threshold doping concentration ratio value in order to retain a more uniform value for the charge carrier mobility in the first channel layer and to improve performance of the metal oxynitride transistor device.

Another objective of the invention is to provide a metal oxide transistor device having a first channel layer with controlled doping concentration profile in the first channel layer so that doping concentration ratios between a bottom channel region and a central channel region and between a top channel region and the central channel region are greater than a first threshold doping concentration ratio value and smaller than a second threshold doping concentration ratio value in order to retain a more uniform value for the charge carrier mobility in the first channel layer and to improve performance of the metal oxide transistor device.

### BRIEF DESCRIPTION OF THE SEVERAL VIEWS OF THE DRAWINGS

FIG. 1a A schematic diagram of a thin film transistor 200B showing a first substrate (210), a first substrate passivation layer (220), a first gate layer (230), at least a first gate insulating layers (240), a first metal oxynitride or metal oxide active channel layer (250), a drain (260), a source (270), and a first surface passivation layer (280), forming a bottom gate transistor structure.

FIG. 1b A schematic diagram of the first channel layer (250) in FIG. 1a, showing a bottom surface region (250bs), a central channel region (250ce) and a top surface region (250ts).

FIG. 2a A schematic diagram of a thin film transistor 200T showing a first substrate (210′), a first substrate passivation layer (220′), a first metal oxynitride or metal oxide first active channel layer (250′), a drain(260′), a source (270′), at least a first gate insulating layers (240′), a first gate layer (230′) and a first surface passivation layer (280′), forming a top gate transistor structure.

FIG. 2b A schematic diagram of the first channel layer (250′) in FIG. 2a, showing a bottom surface region (250′bs), a central channel region (250′ce) and a top surface region (250′ts).

FIG. 3a A schematic cross sectional diagram for the channel section (200BC) of the thin film transistor (200B) in FIG. 1a, showing a substrate (210) with a first substrate passivation layer (220), a first gate layer (230) and a first gate insulating layer (240), a first metal oxynitride or metal oxide channel layer (250) and a first surface passivation layer (280). The first metal oxynitride or metal oxide channel layer thickness (250t) has been increased for convenience in displaying the top surface region (250ts), the central channel region (250ce) and the bottom surface region (250bs).

FIG. 3b A schematic enlarged cross sectional view for the channel section (200TC) of the thin film transistor (200T) in FIG. 2a, showing a first metal oxynitride or metal oxide channel layer (250′) on a substrate (210′) with a first substrate passivation layer (220′), a first gate insulating layer (240′), a first gate layer (230′) and a first surface passivation layer (280′). The first metal oxynitride or metal oxide channel layer thickness (250′t) has been increased to conveniently display the top surface region (250′ts), the central channel region (250′ce) and the bottom surface region (250′bs).

FIG. 4a A schematic cross sectional diagram for the channel section (200BC) of the bottom gate thin film transistor (200B) in FIG. 1a, showing the first metal oxynitride or metal oxide channel layer (250) on the substrate (210) with the first substrate passivation layer (220). Also showing is the first gate layer (230), the first gate insulating layer (240) and the first surface passivation layer (280). The first metal oxynitride or metal oxide channel layer (250) is divided into three regions and its thickness (250t) has been increased for convenience in displaying the donor doping profile, mobility profile and current density profile in FIGS. 4b, 4c and 4d respectively.

FIG. 4b A diagram shows the donor doping concentration profile N_{c}(y) in the first channel layer (250) having a bottom surface region: 0≦y≦y_{bs}, a central channel region: y_{bs}≦y≦yₜₛ and a top surface region: yₜₛ≦y≦t_{c}, where ratios N_{c}(0)/N_{c}(y_{bs}) and N_{c}(t_{c})/N_{c}(y_{bs}) values in the first channel layer (250) are large and exceeding 100 due to vacancies created from diffusion of oxygen and nitrogen atoms in the surface regions.

FIG. 4c A diagram shows the charge carrier mobility profile μ_{c}(y) in the first channel layer (250) having a bottom surface region: 0≦y≦y_{bs}, a central channel region: y_{bs}≦y≦yₜₛ and a top surface region: yₜₛ≦y≦t_{c}, where ratios μ_{c}(0)/μ_{c}(y_{bs}) and μ_{c}(t_{c})/μ_{c}(y_{bs}) are smaller than 0.1 or less due to excessive coulomb interactions in the surface regions.

FIG. 4d A diagram shows the variation of current density J_{c}(y) in the first channel layer (250) having a bottom surface region: 0≦y≦y_{bs}, a central channel region: y_{bs}>y>yₜₛ and a top surface region: yₜₛ≦y≦t_{c}. The current densities in both surface regions are greater than that in the central channel region J_{c}(y_{bs}) due to larger values for N_{c}(0)/N_{c}(y_{bs}) and N_{c}(t_{c})/N_{c}(y_{bs}) than those for μ(y_{bs})/μ(0) and N_{c}(y_{bs})/μ(t_{c}).

FIG. 4e A diagram shows the variation of charge carrier mobility μ(N_{c}) in an indium oxynitride (InON) semiconductor as a function of the donor doping concentration N_{c}. The rapid decrease in the mobility with the increase in donor concentration N_{c} is the results of the coulomb interactions.

FIG. 5a A schematic cross sectional diagram shows the channel section (200BC) of the bottom gate metal oxynitride or metal oxide transistor (200B, FIG. 1a) with an improved channel doping concentration profile according to this invention.

FIG. 5b A diagram shows the improved doping concentration profile N_{c}(y) in the first channel layer of a metal oxynitride or a metal oxide thin film transistor according to this invention.

FIG. 5c A diagram shows the improved charge carrier mobility profile μ_{c}(y) in the first channel layer of a metal oxynitride or a metal oxide thin film transistor according to this invention.

FIG. 6a A schematic cross sectional diagram shows the channel section (200BC) of the bottom gate metal oxynitride or metal oxide transistor (200B, FIG. 1a) with an improved channel doping concentration profile according to this invention.

FIG. 6b A diagram shows the improved doping concentration profile N_{c}(y) in the first channel layer of a metal oxynitride or a metal oxide thin film transistor according to this invention.

FIG. 6c A diagram shows the improved charge carrier mobility profile μ_{c}(y) in the first channel layer of a metal oxynitride or a metal oxide thin film transistor according to this invention.

FIG. 7a A schematic cross sectional diagram for the channel section (200BC) of the bottom gate metal oxynitride or metal oxide transistor in (200B, FIG. 1a) with an improved channel doping concentration profile according to this invention.

FIG. 7b A diagram shows the improved doping concentration profile N_{c}(y) in the first channel layer of a metal oxynitride or a metal oxide thin film transistor according to this invention.

FIG. 7c A diagram shows the improved charge carrier mobility profile μ_{c}(y) in the first channel layer of a metal oxynitride or a metal oxide thin film transistor according to this invention.

FIG. 8a A schematic cross sectional diagram for the channel section (200BC) of the bottom gate metal oxynitride or metal oxide transistor in (200B, FIG. 1a) with an improved channel doping concentration profile according to this invention.

FIG. 8b A diagram shows the improved donor doping concentration profile N_{c}(y) in the first channel layer of a metal oxynitride or a metal oxide thin film transistor according to this invention.

FIG. 8c A diagram shows the improved charge carrier mobility profile μ_{c}(y) in the first channel layer of a metal oxynitride or a metal oxide thin film transistor.

### DETAIL DESCRIPTION OF THE PREFERRED EMBODIMENTS

According to one embodiment of this invention, a metal oxynitride thin film transistor or a metal oxide thin film transistor (200B) with a bottom gate structure for forming an electronic circuit is provided in FIG. 1a. The thin film transistor (200B) comprises a substrate (210) having a substrate thickness (210t), a substrate passivation layer (220) with a substrate passivation layer thickness (220t) to achieve isolation from the substrate; at lease a first gate layer (230) having a first gate layer thickness (230t) and a first gate layer length (230L); a first gate insulating layer (240) having a first gate insulating layer thickness (240t); at least a first metal oxynitride or metal oxide channel layer (250) with a first channel layer thickness (250t); a drain layer (260) with a drain layer thickness (260t); a source layer (270) with a source layer thickness (270t); and a first surface passivation layer (280) with a first surface passivation layer thickness (280t), forming a bottom gate thin film transistor (200B). A channel section of the thin film transistor (200B) is defined by (200BC) in FIG. 1a. The channel length of the thin film transistor (200B) is given by the first gate layer length (230L). In FIG. 1b, a cross sectional view of the first metal oxynitride or metal oxide channel layer (250) is shown to have three regions: a bottom surface region (250bs) with a bottom surface region thickness t_{bs} and a bottom surface region doping concentration N_{cb}, a central channel region (250ce) with a central region thickness t_{ce} and a central region doping concentration N_{cc}, and a top surface region (250ts) with a top surface region thickness tₜₛ and a top surface region doping concentration N_{ct}. The total thickness (250t) of the first channel layer (250) is given by t_{c} in FIG. 1 b.

In order to improve the performance of the thin film transistor (200B), according to one embodiment of the invention, the ratio between the bottom surface region doping concentration N_{cb} and the central region doping concentration N_{cc} is controlled to be substantially greater than a first threshold doping concentration ratio T_{c1} and to be smaller than a second threshold doping concentration ratio T_{c2}. The ratio between the top surface region doping concentration N_{ct} and the central region doping concentration N_{cc} is also controlled to be substantially greater than the first threshold doping concentration ratio T_{c1} and to be smaller than the second threshold doping concentration ratio T_{c2}. In order to retain a high and more uniform charge carrier mobility in the first metal oxynitride or metal oxide channel layer (250) and to improve performance of the thin film transistor (200B), the first threshold doping concentration ratio T_{c1} is preferably selected to be 0.01 and is more preferably selected to be 0.1, whereas the second threshold doping concentration ratio T_{c2} is preferably selected to be 100 and is more preferably selected to be 10.

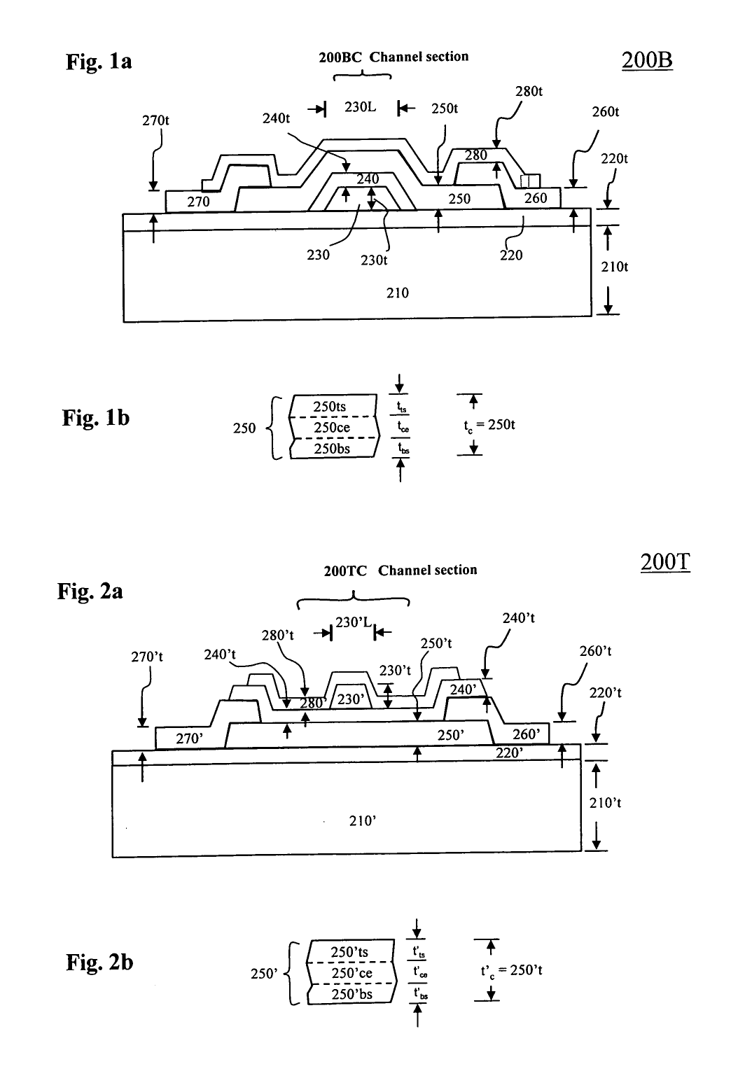

It is noted that embodiments for this invention may well be suited for a top gate transistor structure as shown in FIG. 2a. According to this invention, a metal oxynitride thin film transistor or a metal oxide thin film transistor (200T) comprises a substrate (210′) having a substrate thickness (210′t); a substrate passivation layer (220′) with a substrate passivation layer thickness (220′t); at least a first metal oxynitride or metal oxide channel layer (250′) with a first channel layer thickness (250′t); a drain layer (260′) with a drain layer thickness (260′t); a source layer (270′) with a source layer thickness (270′t); at least a first gate insulating layer (240′) having a first gate insulating layer thickness (240′t); at lease a first gate layer (230′) having a first gate layer thickness (230′t) and a first gate layer length (230′L), a first surface passivation layer (280′) with a first surface passivation layer thickness (280′t), forming a top gate thin film transistor (200T). A channel section of the thin film transistor (200T) is defined by (200TC) in FIG. 2a. The channel length of the thin film transistor (200T) is given by the first gate layer length (230′L). FIG. 2b shows a cross sectional view of the first channel layer (250′) in thin film transistor (200T). In FIG. 2b, the first metal oxynitride or metal oxide channel layer (250′) is divided into three regions: a bottom surface region (250′bs) with a bottom surface region thickness t′_{bs} and a bottom surface region doping concentration N_{cb}; a central channel region (250′ce) with a central region thickness t′_{ce} and a central region doping concentration N′_{cc}; and a top surface region (250′ts) with a top surface region thickness eₜₛ and a top surface region doping concentration N′_{ct}. The total thickness (250′t) of the first channel layer (250′) is given by t′_{c} in FIG. 2b.

In order to improve the performance of the thin film transistor (200T), according to one embodiment of the invention, the ratio between the bottom surface region doping concentration N′_{cb} and the central region doping concentration N′_{cc} is controlled to be substantially greater than a first threshold doping concentration ratio T_{c1} and to be smaller than a second threshold doping concentration ratio T_{c2}. The ratio of the top surface region doping concentration N′_{ct} to the central region doping concentration N′_{cc} is also controlled to be substantially greater than the first threshold doping concentration ratio T_{c1} and to be smaller than the second threshold doping concentration ratio T_{c2}. In order to retain high and more uniform charge carrier mobility in the first channel layer (250′) and to improve performance of the thin film transistor device (220T), the first threshold doping concentration ratio T_{c1} is preferably selected to be 0.01 and is more preferably selected to be 0.1, whereas the second threshold doping concentration ratio T_{c2} is preferably selected to be 100 and is more preferably selected to be 10.

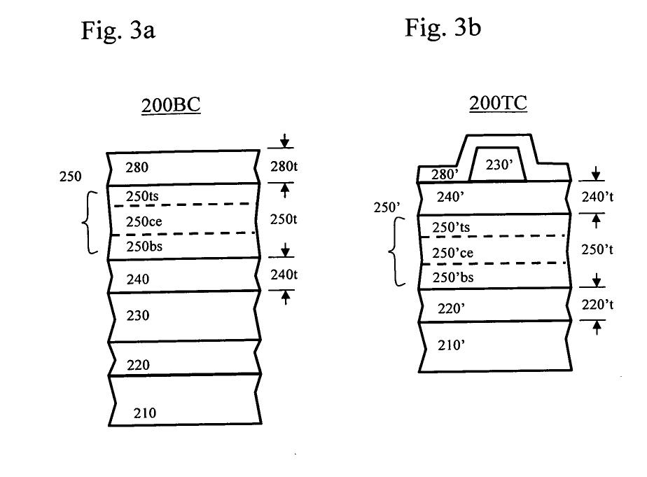

FIG. 3a is a schematic cross sectional view of the channel section (200BC, FIG. 1a) of the bottom gate metal oxynitride or a metal oxide thin film transistor (200B), showing a substrate (210) with a substrate passivation layer (220), a first gate layer (230), a first gate insulating layer (240), a first metal oxynitride or metal oxide channel layer (250) and a first surface passivation layer (280). The first channel layer (250) has a top surface region (250ts), a central channel region (250ce) and a bottom surface region (250bs). FIG. 3b shows schematic cross sectional diagram of the channel section (200TC, FIG. 2a) of the top gate metal oxynitride or metal oxide thin film transistor (200T), showing a first metal oxynitride or metal oxide channel layer (250′) on a substrate (210′) with a substrate passivation layer (220′) having a substrate passivation thickness (220′t), a first gate insulating layer (240′), a first gate layer (230′) and a first surface passivation layer (280′). The first channel layer (250′) has a top surface region (250′ts), a central channel region (250′ce) and a bottom surface region (250′bs).

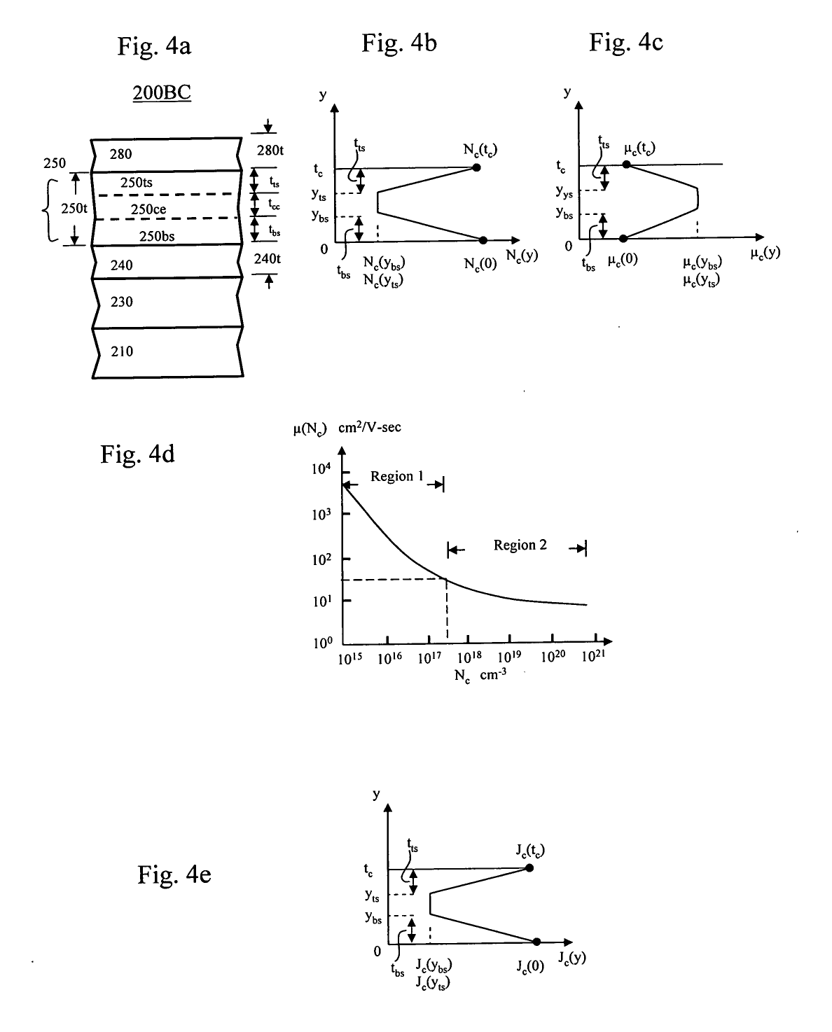

For simplicity reasons, the schematic cross-sectional view of the channel section (200BC) for the bottom gate metal oxynitride or metal oxide thin film transistor (200B) will be adopted in FIGS. 4 to 8 for subsequent description of the present invention. It is noted that the embodiments for improving the performance of a metal oxynitride or metal oxide thin film transistor according to this invention are equally well suited for the top gate thin film transistor structure and the bottom gate thin film transistor structure.

In order to achieve high charge carrier mobility, the metals for forming the first metal oxynitride or metal oxide channel layer (250, 250′) are selected from a group including: In, Zn, Sn, Ga, Ba, La, Al, Mg and their mixtures. Material examples for the metal oxynitrides may include: InO_{y}N_{1-y}, InₓSn₁₋ₓO_{y}N_{1-y}, InₓZn₁₋ₓO_{y}N_{1-y}, InₓGa₁₋ₓO_{y}N_{1-y}, InₓMg₁₋ₓO_{y}N_{1-y}, SnₓZn₁₋ₓO_{y}N_{1-y}, SnₓBa₁₋ₓO_{y}N_{1-y}, Snₓ(Ba,La)₁₋ₓO_{y}N_{1-y}, here 0≦x≦1 and 0≦y≦1. Since all metal oxynitrides become metal oxides when y equals to 1, the description for metal oxynitride thin film transistors is also suited for a metal oxide thin film transistors.

Additional metal elements such as B, Mg, Ca, Sr and Ba may be added to adjust the conductivity of the channel layer. The exact values of x and y for best performance of the present metal oxynitride transistor are determined by the materials combination.

According to one embodiment of this invention, materials of the gate insulating layer (240, FIGS. 3a and 240′, FIG. 3b) may be selected from a group including: silicon dioxide (SiO₂), silicon nitride (Si₃N₄), aluminum oxide (Al₂O₃), aluminum nitride (AlN), hafnium oxide (HfO₂), gallium oxide (Ga₂O₃), barium strontium titanite and their mixtures, so long as the gate insulating layer has a large breakdown voltage, low leakage current and preferably has negative or low positive fixed charges in the gate insulating layer. Gate insulating layer thickness (240t and 240′t) is selected according to the breakdown voltage and operating frequency required and is often less than 100 nm.

In order to modulate the free charge carriers in the first channel layer in a metal oxynitride or a metal oxide thin film transistor, a voltage applied to the first gate layer (230 or 230′) should be able to vary the depletion region width under (for top gate structure) or above (for bottom gate structure) the first gate layer. Therefore, material of the first gate layer is selected from a group of metals with a large work function, including: Pt, Ni, W, Mo, Ta, Ai, Au, Cu, Ag and their alloys so that a rectifying contact is formed between the first gate layer and the first channel layer (250, 250′). Furthermore, it is obvious that in forming the first gate layer in a bottom gate structure, the last metal material to put down and to contact the first gate insulating layer (240) should have a work function as large as possible. And in forming the first gate layer in a top gate structure, the first metal material to put down and to contact the surface of the first gate insulating layer (240′) should have a work function as large as possible. Such metals are Ni, Pt, Au etc. The length of the first gate layer may be in the range from 50 nm to 3,000 nm or larger, depending on the power handling capability and operating frequency required.

In a metal oxide thin film transistor or a metal oxynitride thin film transistor, some oxygen atoms and/or nitrogen atoms in the bottom surface region will diffuse into the substrate passivation layer (220′, FIG. 3b) for a top gate transistor structure or into the first gate insulating layer (240, FIG. 3a) for a bottom gate transistor structure during the manufacturing. Such diffusion will increase the doping concentration in the bottom surface region so that a ratio between the bottom surface region doping concentration and the central region doping concentration is often much greater than 100. As a result, mobility of charge carriers in the bottom surface region is much smaller than the charge carrier mobility in the central channel region, yielding poor performance of the thin film transistor. Similarly, in such metal oxide thin film transistor or metal oxynitride thin film transistor, some oxygen atoms and/or nitrogen atoms in the top surface region will diffuse out and into the atmosphere (for both top gate transistor structure and bottom gate transistor structure) during the manufacturing. This will results in an increase in the doping concentration in the top surface region so that a ratio between the top surface region doping concentration and the central region doping concentration is often much greater than 100. This in turn will cause the charge carrier mobility in the top surface region to be much smaller than that of the central channel region yielding poor performance of the thin film transistors.

In order to maintain performance of the metal oxynitride or metal oxide thin film transistors, according to one embodiment of this invention, the doping concentrations in the bottom surface region and in the top surface region need to be controlled so that ratio between the top surface region doping concentration and the central channel region doping concentration and the ratio between the bottom surface region doping concentration and the central channel region doping concentration are greater than a first threshold doping concentration ratio value T_{c1} and smaller than a second threshold doping concentration ratio value T_{c2}. Here, T_{c1} is preferably selected as 0.01 and is more preferably selected as 0.1 and T_{c2} is preferably selected as 100 and is more preferably selected as 10.

The schematic cross sectional view of the channel section (200BC, FIG. 3a) of the thin film transistor (200B, FIG. 1a) is shown again in FIG. 4a, including the substrate (210), the first gate layer (230), the first gate insulation layer (240), the first metal oxynitride or metal oxide channel layer (250) and the first surface passivation layer (280). In FIG. 4a, the first channel layer thickness (250t) has been increased for convenience in displaying profiles of doping concentration, charge carrier mobility and current density in FIGS. 4b, 4c and 4e respectively. In FIG. 4b, the first channel layer (250) are represented by: the bottom surface region (250bs, 0≧y≧y_{bs}), the central channel region (250ce, y_{bs}≧y≦yₜₛ) and the top surface region (250ts, yₜₛ≦y≧t_{c}=2500, where y stands for vertical positions in the first channel layer (250) from the bottom surface (y=0) of the first channel layer. In FIG. 4b, the doping concentration profile N_{c}(y) of the first channel layer (250) is shown as a function of the vertical position y. It is noted that due to vacancies created from loss of oxygen and nitrogen atoms in the top and bottom surface regions in the first channel layer, the doping concentration N_{c}(y) is largest at y=0 (N_{c}(0)) and at y=t_{c} (N_{c}(t_{c})) and it decreases gradually and reaches a minimum value N_{c}(yₜₛ) or N_{c}(y_{bs}) in the central channel region (250ce, yₜₛ≧y≧y_{bs}). In other words, average doping concentration (N_{cb} and N_{ct}) in the bottom surface region and in the top surface region are much greater than average doping concentration (N_{cc}) in the central region.

FIG. 4c shows variation of charge carrier mobility μ_{c}(y) in the first channel layer (250). As shown in FIG. 4b, the doping concentrations in the bottom surface region (250bs) and the top surface regions (250ts) are significantly greater than the doping concentration in the central channel region (250ce), so that ratios N_{c}(0)/N_{c}(y_{bs}) and N_{c}(t_{c})/N_{c}(y_{bs})>>100. These result in severe coulomb interactions in both the bottom and the top surface regions, therefore, ratios μc(0)/μ_{c}(y_{bs}) and μ_{c}(t_{c})/μ_{c}(y_{bs}) have values smaller than 0.1 or less. It should be noted that in many metal oxide or metal oxynitride semiconductors, the charge carrier mobility decreases as the doping concentration increases at a slower rate as comparing to the increase rate of the doping concentration, which is reflected in FIGS. 4b and 4c (a deeper slop for N_{c}(y) than μ_{c}(y)).

FIG. 4d is a diagram showing the variation of charge carrier mobility μ_{c}(N_{c}) in a metal oxynitride or metal oxide semiconductor as a function of the doping concentration N_{c}(y). The rapid decrease in the mobility μ_{c} with the increase in the doping concentration N_{c} is due to coulomb interactions. The mobility curve can be divided into two regions: Region 1 where the doping concentration is less than 5×10¹⁷ cm⁻³ and region 2 where the doping concentration is greater than 5×10¹⁷ cm⁻³. In region 1, the charge carrier mobility is greater than 50 cm²N-sec whereas the charge carriers mobility in region 2 is less than 50 cm²N-sec due to more severe coulomb interactions.

FIG. 4e shows the variation of current density J_{c}(y) with y(0≦y≧t_{c}) in the first channel layer (250). Due to larger values for ratios N_{c}(0)/N_{c}(y_{bs}) and N_{c}(t_{c})/N_{c}(y_{bs}) as compared to ratios μ(y_{bs})/μ(0) and μ(y_{bs})/μ(t_{c}), the current densities at a given electric field in both the bottom surface region (250bs) and the top surface region (250ts) are greater than the current density in the central channel region J_{c}(y_{bs}). When a thin film transistor is operated with a large current density in the top surface region (J_{c}(t_{c})) and a large current density in the bottom surface region (J_{c}(0)), the overall channel current or transistor output current will be dominated by the top surface region current and the bottom surface region current. Since the average charge carrier mobilities in the top surface region and bottom surface regions are much smaller than the charge carrier mobility in the central channel region, the average carrier mobility contributing to the overall channel current will be low. Therefore, the performance of the transistor can not be maintained at the same level as that when the average charge carrier mobility is kept close to the central channel region mobility, where the unwanted coulomb interactions are low.

In order to maintain performance of the metal oxynitride or metal oxide thin film transistors, according to one embodiment of this invention, doping concentrations in the bottom surface region and in the top surface region need to be controlled so that a ratio of the top surface region doping concentration to the central channel region doping concentration and a ratio of the bottom surface region doping concentration to the central channel region doping concentration are greater than a first threshold doping concentration ratio value T_{c1} and smaller than a second threshold doping concentration ratio value T_{c2}. Here, T_{c1} is preferably selected as 0.01 and is more preferably selected as 0.1 and T_{c2} is preferably selected to be 100 and is more preferably selected to be 10.

Since high density vacancies lead to excessive coulomb interactions and thus a low charge carrier mobility, therefore, in order to obtain reduced doping concentration ratio values, unwanted high vacancy density in both the bottom surface region and the top surface region arising from the loss of nitrogen and/or oxygen atoms from the surface regions during fabrication must be reduced. According to one embodiment of the invention, the vacancy density in the bottom surface region (250bs or 250′bs, refer to FIGS. 3a and 3b) is reduced by introducing atoms of oxygen and/or nitrogen into the first gate insulating layer (240) for a bottom gate structure (200B) or into the substrate passivation layer (220′) for a top gate structure (200T) before the deposition of the first channel layer (250 or 250′). In subsequent fabrication steps, the atoms of oxygen and nitrogen introduced will diffuse into the bottom surface region of the first channel layer (250 or 250′), to compensate the loss and prevent the creation of high concentration vacancies. The preferred methods to introduce the atoms of oxygen and/or nitrogen are low energy ion implantation and plasma immersion implantation. By controlling the amount of oxygen and nitrogen atoms through the control of dose and energy, the vacancy density in the bottom surface region can be controlled.

According to another embodiment of the invention, the vacancy density in the bottom surface region (250bs and 250′bs, FIGS. 3a and 3b) can be reduced and controlled by introducing atoms of oxygen and/or nitrogen into the bottom surface region directly during the deposition of the first channel layer.

In order to obtain a reduced concentration ratio between the top surface region and the central channel region, the vacancy density in the top surface region (250ts or 250′ts) is reduced by introducing atoms of oxygen and/or nitrogen into the top surface region directly (for both the bottom gate structure and the top gate structure). In subsequent fabrication steps, the atoms of oxygen and nitrogen introduced into the top surface region (250ts or 250′ts) will compensate the loss of oxygen and nitrogen and prevent the creation of high concentration vacancies in the top surface region. The preferred methods to introduce the atoms of oxygen and/or nitrogen are low energy ion implantation and plasma immersion implantation. The vacancy density in the bottom surface region can be controlled by controlling the amount of oxygen and nitrogen atoms introduced through the control of dose and energy during ion implantation and plasma immersion implantation.

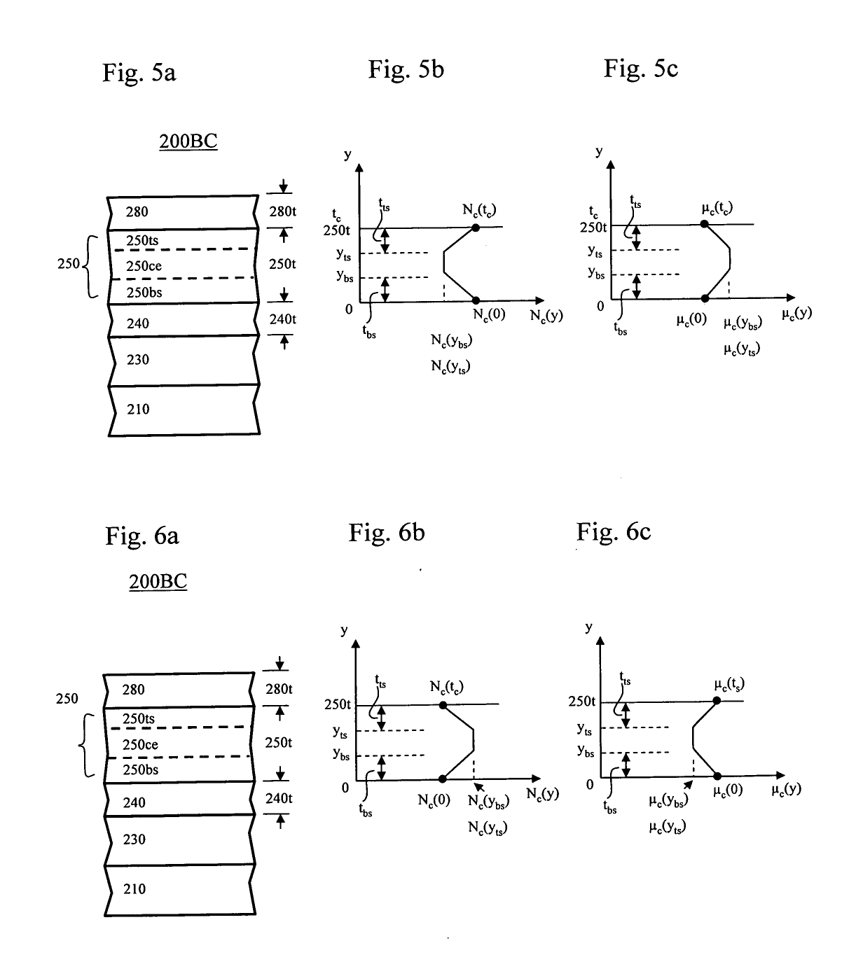

A schematic cross sectional view of the channel section (200BC) of the thin film transistor (200B, FIG. 1a) is shown in FIG. 5a, including a substrate (210), a substrate passivation layer (220), a first gate layer (230), a first gate insulation layer (240), a first metal oxynitride or metal oxide channel layer (250) and a first surface passivation layer (280). In order to obtain reduced doping concentration ratio values as shown in FIG. 5b, according to one embodiment of this invention, the doping concentration in the bottom surface region (250bs) and in the top surface region (250ts) are reduced by introducing oxygen atoms and/or nitrogen atoms into the top surface region and into the bottom surface region during deposition of the first channel layer. In subsequent fabrication, the atoms of oxygen and nitrogen introduced will compensate the loss of oxygen and/or nitrogen in the surface regions of the first channel layer to prevent creation of high concentration vacancies in these regions. The doping concentration in the bottom surface region can also be reduced by introducing oxygen atoms and/or nitrogen atoms into either the first gate insulating layer (240) for the bottom gate structure or into the substrate passivation layer (220′, FIG. 3b) for the top gate structure before the deposition of the first channel layer. The preferred methods to introduce the atoms of oxygen and/or nitrogen are low energy ion implantation and plasma immersion implantation and followed by a rapid thermal annealing for activation of implanted oxygen and/or nitrogen atoms. The density of vacancies in the surface regions can be controlled by controlling the amount of oxygen and nitrogen atoms introduced through the control of dose and energy during ion implantation and plasma immersion implantation.

By doing the low energy ion implantation or plasma immersion implantation with properly controlled energy and dose, the ratio between the top surface region doping concentration and the central channel region doping concentration N_{c}(t_{c})/N_{c}(y_{bs}) and the ratio between the bottom surface region doping concentration and the central channel region doping concentration N_{c}(0)/N_{c}(y_{bs}) can be controlled to be greater than 1 and less than the second threshold doping concentration ratio value T_{c2} (see FIG. 5b). Here T_{c2} is preferably selected as 100 and is more preferably selected as 10 according this invention.

In order to retain the performance of a metal oxynitride or a metal oxide thin film transistor, the ratios between the top surface region mobility and the central channel region mobility μ_{c}(t_{c})/μ(y_{bs}) and between the bottom surface region mobility and the central channel region mobility μ_{c}(0)/μ(y_{bs}) must not be too small and are preferably larger than 0.5, so that an average charge carrier mobility in the first channel layer (250) will not deviate substantially from the charge carrier mobility in the central channel region: μ(y_{bs})=μ(yₜₛ). This requirement can be achieved by properly controlling the doping concentration ratio values. For a doping concentration profile shown in FIG. 5b, the charge carrier mobility in the first channel layer is shown (FIG. 5c) to have a more uniform profile and the ratios μ_{c}(t_{c})/μ(y_{bs}) and μt_{c}(0)/μ(y_{bs}) are larger than 0.5.

According to one other embodiment of the invention, the vacancies in the top surface region and the bottom surface region (250ts and 250bs, FIG. 6a) are reduced by introducing atoms of oxygen and/or nitrogen into the top surface region (250ts in FIG. 6a or 250′ts in FIG. 3b) and into the bottom surface region (250bs and 250′bs) during deposition of the first channel layer (250, 250′). The doping concentration in the bottom surface region can also be reduced by introducing atoms of oxygen and/or nitrogen into either the first gate insulating layer (240, FIG. 6a) for the bottom gate structure or into the substrate passivation layer (220′, FIG. 3b) for the top gate structure before the deposition of the first channel layer. In subsequent fabrication, the atoms of oxygen and nitrogen introduced will compensate the loss of oxygen and nitrogen in the surface regions of the first channel layer, reduce the numbers of vacancies created and prevent creation of high concentration vacancies in these regions. The preferred methods to introduce the atoms of oxygen and/or nitrogen are low energy ion implantation and plasma immersion implantation and followed by a rapid thermal annealing for activation of implanted oxygen and/or nitrogen atoms. The density of the vacancies in the surface regions can be controlled by controlling the amount of oxygen and nitrogen atoms introduced through control of dose and energy during ion implantation and plasma immersion implantation.

By doing the low energy ion implantation or plasma immersion implantation with properly controlled energy and dose, the vacancies in the surface regions can be largely eliminated so that both top surface doping concentration N_{c}(t_{c}) and bottom surface doping concentration N_{c}(0) are less than the central channel region doping concentration N_{c}(y_{bs}) as shown in FIG. 6b. When this occurs, the ratio between the top surface region doping concentration and the central channel region doping concentration N_{c}(t_{c})/N_{c}(y_{bs}) and the ratio between the bottom surface region doping concentration and the central channel region doping concentration N_{c}(0)/N_{c}(yₛ) are less than 1. In order to retain the performance of the metal oxynitride or metal oxide thin film transistor and according to this invention, it is preferred to have the two doping concentration ratios: N_{c}(t_{c})/N_{c}(y_{bs}) and N_{c}(0)/N_{c}(y_{bs}) to be larger than a first threshold doping concentration ratio T_{c1}. Here, T_{c1} is preferably selected as 0.01 and more preferably selected as 0.1.

For a doping concentration profile shown in FIG. 6b, the charge carrier mobility μ_{c}(y) of the three channel regions is shown in FIG. 6c to have a flipped shape as that shown in FIG. 5c. In this case, the top surface region mobility to central channel region mobility ratio μ_{c}(t_{c})/μ(y_{bs}) and bottom surface region mobility to central channel region mobility ratio μ_{c}(0)/μ(y_{bs}) will be desirably greater than 1. According to this invention, in order to achieve improved performance of the metal oxynitride thin film transistor or metal oxide thin film transistor, the mobility ratios are preferably greater than 1 and are more preferably greater than 2 so that the average carrier mobility in the first channel layer will be greater than the carrier mobility in the central channel region: μ(y_{bs})

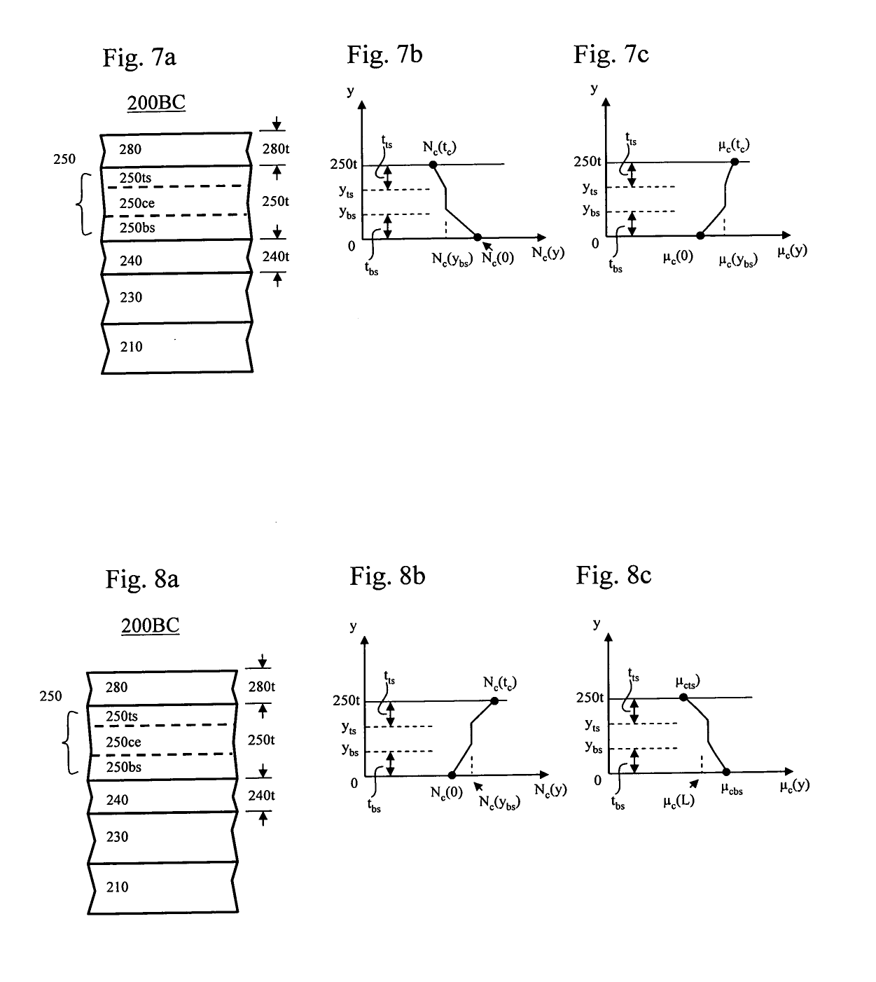

According to another embodiment of this invention, the vacancies in the top surface region and the bottom surface region are reduced by introducing atoms of oxygen and/or nitrogen into the top surface region (250ts in FIG. 7a or 250′ts in FIG. 3b) and into the bottom surface region (250bs and 250′bs) during deposition of the first channel layer (250, 250′). The bottom surface doping concentration can also be reduced by introducing atoms of oxygen and/or nitrogen into either the first gate insulating layer (240, FIG. 7a) for the bottom gate structure or into the substrate passivation layer (220′, FIG. 3b) for the top gate structure. In subsequent fabrication, the atoms of oxygen and nitrogen introduced will compensate the loss of oxygen and nitrogen in the surface regions of the first channel layer and reduce the numbers of vacancies created and prevent creation of high concentration vacancies in these regions. The preferred methods to introduce the atoms of oxygen and/or nitrogen are low energy ion implantation and plasma immersion implantation and followed by a rapid thermal annealing for activation of implanted oxygen and/or nitrogen atoms. The density of the vacancies in the surface regions can be controlled by controlling the amount of oxygen and nitrogen atoms introduced through the control of dose and energy during ion implantation and plasma immersion implantation.

By doing the low energy ion implantation or plasma immersion implantation with properly controlled energy and dose, the vacancies may be reduced in such a fashion so that the resulting top surface region doping concentration N_{c}(t_{c}) is less than the central channel region doping concentration N_{c}(y_{bs}) and the bottom surface doping concentration N_{c}(0) is greater than the central channel region doping concentration N_{c}(y_{bs}), as seen in FIG. 7b. When this occurs, the ratio between the top surface region doping concentration and the central channel region doping concentration: N_{c}(t_{c})/N_{c}(y_{bs})<1 and the ratio between the bottom surface region doping concentration and the central channel region doping concentration: N_{c}(0)/N_{c}(y_{bs})>1. In order to retain the performance of the metal oxynitride or metal oxide thin film transistor and according to this invention, it is preferable to have the ratio N_{c}(t_{c})/N_{c}(y_{bs}) larger than a first threshold doping concentration ratio T_{c1} and the ratio N_{c}(0)/N_{c}(y_{bs}) smaller than a second doping concentration ratio T_{c2}. Here, the value of T_{c1} is preferably selected as 0.01 and is more preferably selected as 0.1 and the value of T_{c2} is preferably selected to be 100 and is more preferably selected to be 10 according to the invention.

For a doping concentration profile shown in FIG. 7b, the profile of the charge carrier mobility μ_{c}(y) in the first channel layer is shown in FIG. 7c. The ratio of the top surface region mobility to the central channel region mobility μ_{c}(t_{c})/μ(y_{bs}) is seen slightly greater than 1 and the ratio of the bottom surface region mobility to central channel region mobility μt_{c}(0)/μ(y_{bs}) is slightly less than 1. In order to achieve improved performance of the metal oxynitride or metal oxide thin film transistor and according to the invention, the ratio μ_{c}(0)/μ(y_{bs}) is preferably controlled to be larger than 0.5 and close to 1 and the ratio μ_{c}(t_{c})/μ(y_{bs}) is preferably controlled to be smaller than 1.5 and close to 1 by controlling the doping concentration ratios, so that the average charge carrier mobility in the first channel layer (250, 250′) will not be substantially different from the charge carrier mobility in the central channel region: μ(y_{bs}).

According to still another embodiment of the present invention, the vacancies in the top surface region and the bottom surface region of the first channel layer are reduced by introducing atoms of oxygen and/or nitrogen into the top surface region (250ts in FIG. 8a or 250′ts in FIG. 3b) and into the bottom surface region (250bs and 250′bs) during deposition of the first channel layer (250, 250′). The bottom surface doping concentration can also be reduced by introducing atoms of oxygen and/or nitrogen into either the first gate insulating layer (240, FIG. 8a) for the bottom gate structure or into the substrate passivation layer (220′, FIG. 3b) for the top gate structure. In subsequent fabrication, the atoms of oxygen and nitrogen introduced will compensate the loss the oxygen and nitrogen atoms in the surface regions of the first channel layer and reduce the numbers of vacancies created and prevent creation of high concentration vacancies in these regions. The preferred methods to introduce the atoms of oxygen and/or nitrogen are low energy ion implantation and plasma immersion implantation and followed by a rapid thermal annealing for activation of implanted oxygen and/or nitrogen atoms. The density of the vacancies in the surface regions can be controlled by controlling the amount of oxygen and nitrogen atoms introduced through the control of dose and energy during ion implantation and plasma immersion implantation.

By doing the low energy ion implantation or plasma immersion implantation with properly controlled energy and dose, the vacancies are reduced in such a fashion so that the resulting top surface doping concentration N_{c}(t_{c}) is slightly greater than the central region doping concentration N_{c}(y_{bs}) and the bottom surface doping concentration N_{c}(0) is slightly less than the central channel region doping concentration N_{c}(y_{bs}) as see in FIG. 8b. When this occurs, the ratio between the top surface region doping concentration and the central channel region doping concentration: N_{c}(t_{c})/N_{c}(y_{bs})>1 and the ratio between the bottom surface region doping concentration and the central channel region doping concentration: N_{c}(0)/N_{c}(y_{bs})<1. In order to retain the performance of the metal oxynitride or metal oxide thin film transistor and according to this invention, it is preferable to have the doping concentration ratio N_{c}(t_{c})/N_{c}(y_{bs}) smaller than a second threshold doping concentration ratio value T_{c2} and to have the doping concentration ratio N_{c}(0)/N_{c}(y_{bs}) larger than a first threshold doping concentration ratio value T_{c1}. The value of T_{c2} is preferably selected to be 100 and is more preferably selected to be 10 and the value of T_{c1} is preferably selected to be 0.01 and is more preferably selected to be 0.1, according to this invention.

For a metal oxynitride or metal oxide thin film transistor with a doping concentration profile shown in FIG. 8b, the charge carrier mobility μ_{c}(y) profile for the three channel regions is shown in FIG. 8c. The ratio of the top surface region mobility to the central channel region mobility μ_{c}(t_{c})/μ(y_{bs}) is seen to be greater than 0.5 and less than 1 and the ratio of the bottom surface region mobility to the central channel region mobility μ_{c}(0)/μ(y_{bs}) is seen to be greater than 1. In order to achieve improved performance of the metal oxynitride or metal oxide thin film transistor and according to the invention, the ratio μ_{c}(0)/μ(y_{bs}) is preferably controlled to be smaller than 1.5 and close to 1 and the ratio μ_{c}(t_{c})/μ(y_{bs}) is preferably controlled to be larger than 0.5 and close to 1 by controlling the doping concentration ratios, so that average carrier mobility in the first metal oxynitride/oxide channel layer (250, or 250′) will not be substantially different from carrier mobility in the central channel region: μ_{c}(y_{bs}).

According to one embodiment of this invention, materials of the gate insulating layer (240, FIGS. 3a and 240′, FIG. 3b) may be selected from a group including: silicon dioxide (SiO₂), silicon nitride (Si₃N₄), aluminum oxide (Al₂O₃), aluminum nitride (AlN), hafnium oxide (HfO₂), gallium oxide (Ga₂O₃), barium strontium titanite and their mixtures, so long as the gate insulating layer has a large breakdown voltage, low leakage current and preferably has negative or low positive fixed gate insulating charges. Gate insulating layer thickness (240t and 240′t) is selected according to the breakdown voltage and operating frequency required and is often less than 100 nm.

In order to modulate the free charges in the first metal oxynitride channel layer in the metal oxynitride transistor, a voltage applied to the first gate layer (230 or 230′) should be able to vary the depletion region width under the first gate layer (for top gate structure) or above the first gate layer (for bottom gate structure). Therefore material of the first gate layer is selected from a group of large work function metals including: Pt, Ni, W, Mo, Ta, Ai, Au, Cu, Ag and their alloys so that a rectifying contact is formed between the first gate layer and the first metal oxynitride or metal oxide channel layer (250, 250′). Furthermore, it is obvious that in forming the first gate layer in a bottom gate structure, the last metal material to put down and to contact the first gate insulating layer should have a work function as large as possible. And in forming the first gate layer in a top gate structure, the first metal material to put down and to contact the surface of the first gate insulating layer should have a work function as large as possible. Such metals are Ni, Pt, Au etc. The length of the first gate layer may be in the range from 50 nm to 3,000 nm or larger, depending on the power handling capability and operating frequency required.

In order to achieve charge carrier mobility, the metals for forming the first metal oxynitride or metal oxide channel layer (250, 250′) are selected from a group including: In, Zn, Sn, Ga, Ba, La, Al, Mg and their mixtures. Some material examples for the metal oxynitrides include: InO_{y}N_{1-y}, InₓSn₁₋ₓO_{y}N_{1-y}, InₓZn₁₋ₓO_{y}N_{1-y}, InₓGa₁₋ₓO_{y}N_{1-y}, InₓMg₁₋ₓO_{y}N_{1-y}, SnₓZn₁₋ₓO_{y}N_{1-y}, SnₓBa₁₋ₓO_{y}N_{1-y}, Snₓ(Ba,La)₁₋ₓO_{y}N_{1-y}, here 0≦x≦1 and 0≦y≦1. Additional metal elements such as B, Mg, Ca, Sr and Ba may be added to adjust the conductivity of the channel layer. The exact values of x and y for best performance of the present metal oxynitride transistor are determined by the material combinations.

According still another embodiment of this invention, for a metal oxynitride or a metal oxide thin film transistor, the central region doping concentration is preferred to be less than 10¹⁹cm⁻³ and more preferred to be less than 10¹⁸ cm⁻³.

According to one embodiment of this invention, materials for the source layer (270, 270′, FIGS. 1a and 2a) and the drain layer (260, 260′) are selected from a material group including: Au, Al, Cu, Ag, Ti, W, Ta, Mo and their alloys in order to reduce unwanted series resistance.

According to still another embodiment of this invention, a metal oxynitride or a metal oxide thin film transistor for forming an electronic circuit, wherein the substrate (210, 210′ FIGS. 1a and 2a) is selected from a group of: glass sheet, plastic sheet, alumina sheet, aluminum nitride sheet, stainless sheet, silicon, gallium arsenide, and silicon with prefabricated digital microelectronic circuits.

Since all the metal oxynitrides become metal oxides when y is selected to be 1, the description for metal oxynitride thin film transistor is also true for a metal oxide thin film transistor. Hence, it should be pointed out all claims for improved metal oxynitride thin film transistors are also suited for metal oxide thin film transistors.

1. A metal oxynitride thin film transistor for forming an electronic circuit, comprises:
a substrate;
a substrate passivation layer;
a first metal oxynitride channel layer with a first channel layer thickness, including a bottom surface region with a bottom surface region thickness and a bottom surface region doping concentration; a central channel region with a central channel region thickness and a central channel region doping concentration; a top surface region with a top surface region thickness and a top surface region doping concentration;
a source layer with a source layer thickness, a drain layer with a drain layer thickness;
at least a first gate insulator layer with a gate insulator layer thickness;
at least a first gate layer with a first gate layer thickness; and
a surface passivation layer,
wherein said bottom surface region doping concentration and said top surface region doping concentration are controlled so that ratios between said bottom surface region doping concentration and said central channel region doping concentration and between said top surface region doping concentration and said central channel region doping concentration are greater than a first threshold doping concentration ratio and smaller than a second threshold doping concentration ratio in order to retain mobility of charge carriers in said first metal oxynitride channel layer and to improve performance of said metal oxynitride thin film transistor.

2. A metal oxynitride thin film transistor for forming an electronic circuit as claimed in claim 1, wherein said first threshold doping concentration ratio is preferably selected as 0.01 and wherein said second threshold doping concentration ratio is preferably selected as 100.

3. A metal oxynitride thin film transistor for forming an electronic circuit as defined in claim 1, wherein metals for forming said first metal oxynitride channel layer is selected from a group of: In, Zn, Sn, Ga, Ba, La, B, Al, Mg, Ca, Sr. Ba and their mixtures.

4. (canceled)

5. (canceled)

6. A metal oxynitride thin film transistor for forming an electronic circuit as defined in claim 1, wherein said top surface region doping concentration is reduced by introducing atoms of oxygen and nitrogen into said top surface region of said first metal oxynitride channel layer.

7. A metal oxynitride thin film transistor for forming an electronic circuit as defined in claim 1, wherein said top surface region doping concentration is controlled by controlling amount of atoms of oxygen and nitrogen introduced into said top surface region of said first metal oxynitride channel layer.

8. A metal oxynitride thin film transistor for forming an electronic circuit as defined in claim 1, wherein said bottom surface region doping concentration is reduced by introducing atoms of oxygen and nitrogen into said substrate passivation layer.

9. A metal oxynitride thin film transistor for forming an electronic circuit as defined in claim 1, wherein said bottom surface region doping concentration is controlled by controlling amount of atoms of oxygen and nitrogen introduced into said substrate passivation layer.

10. A metal oxynitride thin film transistor for forming an electronic circuit as defined in claim 1, wherein said bottom surface region doping concentration is reduced by incorporating atoms of oxygen and nitrogen into said bottom surface region of said first metal oxynitride channel layer.

11. A metal oxynitride thin film transistor for forming an electronic circuit as defined in claim 1, wherein said bottom surface region doping concentration is controlled by controlling amount of atoms of oxygen and nitrogen introduced into said bottom surface region of said first metal oxynitride channel layer.

12. A metal oxynitride thin film transistor for forming an electronic circuit as defined in claim 1, wherein materials of said source and said drain are selected from a metal group including: Au, Al, Cu, Ag, Ti, W, Ta, Mo and their alloys.

13. A metal oxynitride thin film transistor for forming an electronic circuit as defined in claim 1, wherein materials of said first gate layer are selected from a group of high work function metals: Pt, Ni, W, Ta, Mo, Au Cu, Ag and their alloys.

14. A metal oxynitride thin film transistor for forming an electronic circuit as defined in claim 1, wherein said substrate is selected from a group of glass sheet, plastic sheet, alumina sheet, aluminum nitride sheet, stainless sheet, silicon, gallium arsenide, and silicon with prefabricated digital microelectronic circuits.

15. A metal oxynitride thin film transistor for forming an electronic circuit as defined in claim 1, wherein said central channel region doping concentration is preferably less than 10¹⁹ cm⁻³ and is more preferably less than 10¹⁸ cm⁻³.

16-22. (canceled)
